(19) United States
(12) Patent Application Publication
(10) Pub. No.: US 2020/0184222 A1
(43) Pub. Date: Jun. 11, 2020

(54) AUGMENTED REALITY TOOLS FOR LIGHTING DESIGN

(71) Applicant: Electronic Theatre Controls, Inc., Middleton, WI (US)

(72) Inventors: Christopher Mizerak, Oceanside, CA (US); Koen Buys, Hofstade (BE)

(21) Appl. No.: 16/708,775

(22) Filed: Dec. 10, 2019

Related U.S. Application Data
(60) Provisional application No. 62/777,490, filed on Dec. 10, 2018.
(60) Provisional application No. 62/777,466, filed on Dec. 10, 2018.

(51) Int. Cl. G06K 9/00; G06F 3/0484; G06F 3/0485; G06T 15/50; G06F 30/12; G06F 30/13

(52) U.S. Cl. CPC G06K 9/00671; G06F 3/04842; G06F 3/04855; G06T 2215/16; G06F 30/12; G06F 30/13; G06T 15/506

(57) ABSTRACT

A lighting fixture at a venue is controllable using augmented reality on a user-device that displays virtual elements on an image of the lighting fixture and/or a scene at the venue. User input for controlling the lighting fixture is received via the virtual elements and a signal is transmitted by the user device to alter the lighting fixture in the venue based on the user input. The virtual elements change in the display to reflect the change of state of the actual lighting fixture. Altering the lighting fixture includes changing brightness, color, or focus of light, or changing a position of the lighting fixture. The virtual elements may include a selection box around the lighting fixture, manufacturer data, channel numbers, DMX addresses, diagnostic information, a slider, a switch, a knob, a button, a virtual lighting shutter, pan/tilt axes, a moveable virtual beam of light, or a scenery element.

### CROSS-REFERENCE TO RELATED APPLICATIONS

This application claims the benefit of U.S. Provisional Patent Application No. 62/777,490, filed on Dec. 10, 2018, and U.S. Provisional Patent Application No. 62/777,466, filed on Dec. 10, 2018, the entire contents of both of which are hereby incorporated by reference.

### FIELD

Embodiments described herein relate to controlling one or more lighting fixtures.

### SUMMARY

Lighting designers, lighting console operators, and/or lighting system technicians would benefit from an intuitive application for controlling lighting fixtures via a display device. Current methods for controlling lighting fixtures often involve software and/or hardware solutions with primitive calculator-style user interfaces. Visual display information must also be meticulously programmed into the system to be appropriately expressed via the user interface. Unfortunately, complex lighting device data in these systems is often displayed in the form of a spreadsheet. This type of interface requires detailed familiarity with the lighting system in order to troubleshoot problems, make adjustments, and create new visual displays. The user must mentally convert what the user wants to see in a real-world display into the appropriate commands in the lighting control calculations. This process can be slow, cumbersome, and inefficient, and a skilled and experienced user is often required.

Lighting design decisions often must also be made under conditions similar to those of an actual performance. For example, the appearance and movement of the performers may need to be taken into account in the lighting design, which may require performers to be present during the programming of lighting effects. Such a requirement may be expensive or impossible in some circumstances. Managing these issues can squander setup time and make the lighting design process inefficient.

With conventional lighting design techniques, users must also memorize various conditions at a venue (e.g., where potential on-stage hazards are located). For example, hazards such as trap doors, areas beneath scenery elements that are to be lowered onto the stage, and other potentially dangerous elements have to be mentally tracked by the user to keep the performers out of danger during a dress rehearsal or live event. Visually marking such areas can interfere with the visual impression of the venue.

To address the above concerns, systems and methods described herein provide an augmented reality control interface for lighting design. The augmented reality interface alleviates the disconnect a user currently experiences between a visual display of real-world elements and the calculator-style interface of typical lighting control systems. The augmented reality interface could further serve as a design template that can be used at any time of day. Additionally, the augmented reality interface could provide virtual indicators of hazards to notify the user without sacrificing the visual impression of the venue.

Methods described herein provide for controlling a lighting fixture. The methods include capturing, using a camera, image data of the lighting fixture, generating, using an electronic processor, a display including a representation of the lighting fixture on a display device, generating, using the electronic processor, one or more virtual elements, and augmenting, using the electronic processor, the representation of the lighting fixture in the display with the one or more virtual elements. The methods also include receiving, with the electronic processor, an input via the one or more virtual elements in the display to control the lighting fixture, and generating, using the electronic processor, a control signal to alter a characteristic of the lighting fixture in response to the input.

In some embodiments, the display includes surroundings of the lighting fixture that are captured in the image data of the lighting fixture.

In some embodiments, the one or more virtual elements include interactive virtual elements, and the receiving, with the electronic processor, the input via the one or more virtual elements to control the lighting fixture includes receiving the input as a result of user interaction with the one or more virtual elements in the display.

In some embodiments, the methods also include generating, using the electronic processor, the display with the one or more virtual elements in a changed state after generating the control signal in response to the input.

In some embodiments, the control signal is operable for changing a brightness of light produced by the lighting fixture, changing a color of light produced by the lighting fixture, changing a focus of light produced by the lighting fixture, changing an angular position of the lighting fixture, changing a projected image produced by the lighting fixture, changing a projected video produced by the lighting fixture, changing an effect of the light produced by the lighting fixture (e.g., a strobe effect, a fade effect, a swipe effect, or the like), some combination thereof, or the like.

In some embodiments, the one or more virtual elements include manufacturer data of the lighting fixture, channel numbers of the lighting fixture, digital multiplex addresses of the lighting fixture, diagnostic information of the lighting fixture, a slider, a switch, a knob, a button a virtual shutter, a virtual axis of one of pan and tilt of the lighting fixture, a color palette, information relating to light produced by the lighting fixture, and/or a selection box surrounding the lighting fixture to allow the user to select the lighting fixture for the altering of the lighting fixture.

Systems described herein provide for controlling a lighting fixture. The systems include a display device and a controller including an electronic processor coupled to a memory. The memory stores instructions that when executed by the electronic processor configure the controller to receive image data of the lighting fixture from a camera, generate a display including a representation of the lighting fixture on a display device, generate one or more virtual elements, augment the representation of the lighting fixture in the display with the one or more virtual elements, receive an input via the one or more virtual elements in the display to control the lighting fixture, and generate a control signal to alter a characteristic of the lighting fixture in response to the input.

In some embodiments, the display includes surroundings of the lighting fixture that are captured in the image data of the lighting fixture.

In some embodiments, the one or more virtual elements include interactive virtual elements, and the input is received as a result of user interaction with the one or more virtual elements in the display.

In some embodiments, the controller is further configured to generate the display with the one or more virtual elements in a changed state after the control signal is generated in response to the input.

In some embodiments, the control signal is operable to change a brightness of light produced by the lighting fixture, change a color of light produced by the lighting fixture, change a focus of light produced by the lighting fixture, and/or change an angular position of the lighting fixture.

In some embodiments, the one or more virtual elements includes manufacturer data of the lighting fixture, channel numbers of the lighting fixture, digital multiplex addresses of the lighting fixture, diagnostic information of the lighting fixture, a slider, a switch, a knob, a button a virtual shutter, a virtual axis of one of pan and tilt of the lighting fixture, a color palette, information relating to light produced by the lighting fixture, and/or a selection box surrounding the lighting fixture to allow the user to select the lighting fixture for the altering of the lighting fixture.

Methods described herein provide for controlling a device in a lighting system. The methods include capturing, with a camera, an image of a scene to be illuminated by a lighting fixture, generating, using an electronic processor, a display including a representation of the scene on a display device, generating, using the electronic processor, one or more virtual elements associated with the device, and augmenting, using the electronic processor, the representation of the scene in the display with the one or more virtual elements. The methods also include receiving, with the electronic processor, an input via the one or more virtual elements in the display to control the device in the lighting system, and generating, using the electronic processor, a control signal to alter a characteristic of the device in response to the input.

In some embodiments, the one or more virtual elements include interactive virtual elements, and the receiving, with the electronic processor, the input via the one or more virtual elements to control the device includes receiving the input as a result of user interaction with the one or more virtual elements in the display.

In some embodiments, the methods also include generating, using the electronic processor, the display with the one or more virtual elements in a changed state after generating the control signal in response to the input.

In some embodiments, the control signal is operable for changing a brightness of light produced by the lighting fixture, changing a color of light produced by the lighting fixture, changing a focus of light produced by the lighting fixture, and/or changing an angular position of the lighting fixture.

In some embodiments, the one or more virtual elements include a virtual beam of light associated with a lighting fixture, a hoist control to initiate movement of scenery elements, a scenery element, an outline indicating a danger area, a trap door, a fan, and/or a smoke machine.

Systems described herein provide for controlling a device in a lighting system. The systems include a display device and a controller. The controller includes an electronic processor coupled to a memory. The memory stores instructions that when executed by the electronic processor, configure the controller to receive, from a camera, image data of a scene to be illuminated by a lighting fixture, generate a display including a representation of the scene on a display device, generate one or more virtual elements associated with the device, augment the representation of the scene in the display with the one or more virtual elements, receive an input via the one or more virtual elements in the display to control the device in the lighting system, and generate a control signal to alter a characteristic of the device in response to the input.

In some embodiments, the one or more virtual elements include interactive virtual elements, and the receiving of the input via the one or more virtual elements to control the device includes receiving the input as a result of user interaction with the one or more virtual elements in the display.

In some embodiments, the controller is further configured to generate the display with the one or more virtual elements in a changed state after the control signal is generated in response to the input.

In some embodiments, the control signal is operable to change a brightness of light produced by the lighting fixture, change a color of light produced by the lighting fixture, change a focus of light produced by the lighting fixture, and/or change an angular position of the lighting fixture.

In some embodiments, the one or more virtual elements include a virtual beam of light associated with a lighting fixture, a hoist control to initiate movement of scenery elements, a scenery element, an outline indicating a danger area, a trap door, a fan, and/or a smoke machine.

Before any embodiments are explained in detail, it is to be understood that the embodiments are not limited in its application to the details of the configuration and arrangement of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software based devices, as well as a plurality of different structural components, may be utilized to implement the embodiments. For example, “servers” and “computing devices” described in the specification can include one or more processing units, one or more computer-readable medium modules, one or more input/output interfaces, and various connections (e.g., a system bus) connecting the components.

Other aspects of the embodiments will become apparent by consideration of the detailed description and accompanying drawings.

### BRIEF DESCRIPTION OF THE DRAWINGS

FIG. 1 illustrates a system for controlling a lighting fixture using an augmented reality interface.

FIG. 1A illustrates an alternative system for controlling a lighting fixture using an augmented reality interface.

FIG. 2 illustrates a controller for the system of FIG. 1.

FIG. 2A illustrates a controller for the system of FIG. 1A.

FIG. 3 illustrates a camera and a lighting fixture in a venue for the system of FIG. 1.

FIG. 3A illustrates a camera and a lighting fixture in a venue for the system of FIG. 1A.

FIG. 4 illustrates an application display including a lighting fixture and virtual elements.

FIG. 5 illustrates the application display of FIG. 4 on a user device.

FIG. 6 illustrates additional user devices for the system of FIG. 1.

FIG. 7 illustrates an application display including a scene to be illuminated and virtual elements.

FIG. 8 illustrates another application display including the scene of FIG. 7 and different virtual elements.

FIG. 9 illustrates an application display showing both lighting fixtures and a scene to be illuminated by the lighting fixtures.

FIG. 10 illustrates a flowchart of a method of controlling a lighting fixture using an augmented reality interface.

FIG. 11 illustrates another flowchart of a method of controlling a lighting fixture using an augmented reality interface.

FIG. 12 illustrates cameras and lighting fixtures in a venue for the system of FIG. 1.

FIG. 12A illustrates cameras and lighting fixtures in a venue for the system of FIG. 1A.

FIG. 13 illustrates an example of an application interface screen for use with the system of FIG. 1 and/or FIG. 1A that controls the movement of a lighting fixture according to a user input.

FIG. 14 illustrates a scan of a surface a camera may detect to determine a centroid of a lighting beam.

FIG. 15 illustrates an example of an application interface screen for use with the system of FIG. 1 and/or FIG. 1A that controls the movement of the lighting fixture according to a user input designating the lighting beam destination.

FIG. 16 illustrates a process for determining a lighting fixture arrangement.

FIG. 17 illustrates a process for determining a lighting fixture arrangement.

FIG. 18 illustrates a process for directing a lighting fixture in a venue.

### DETAILED DESCRIPTION

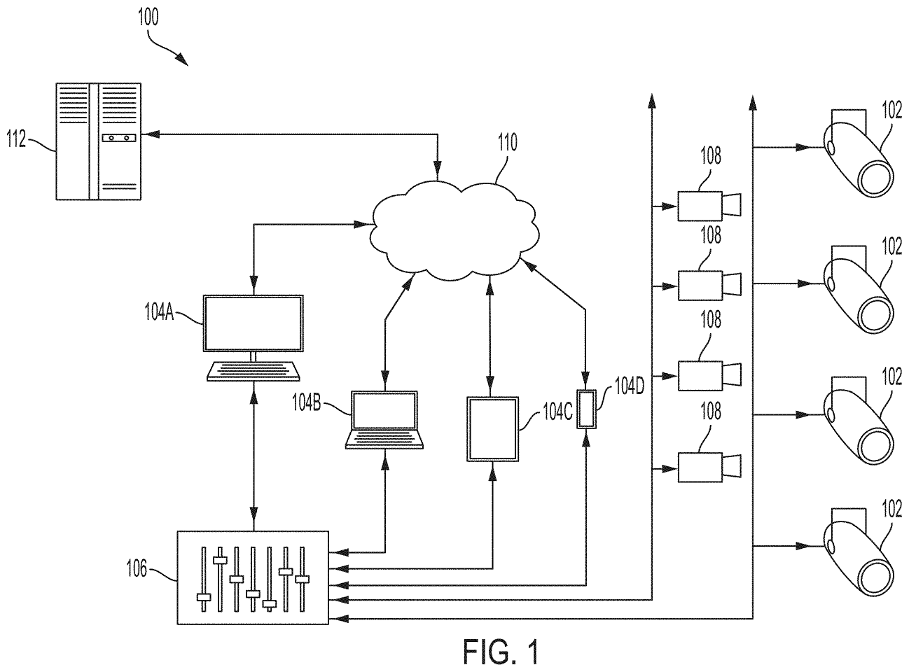

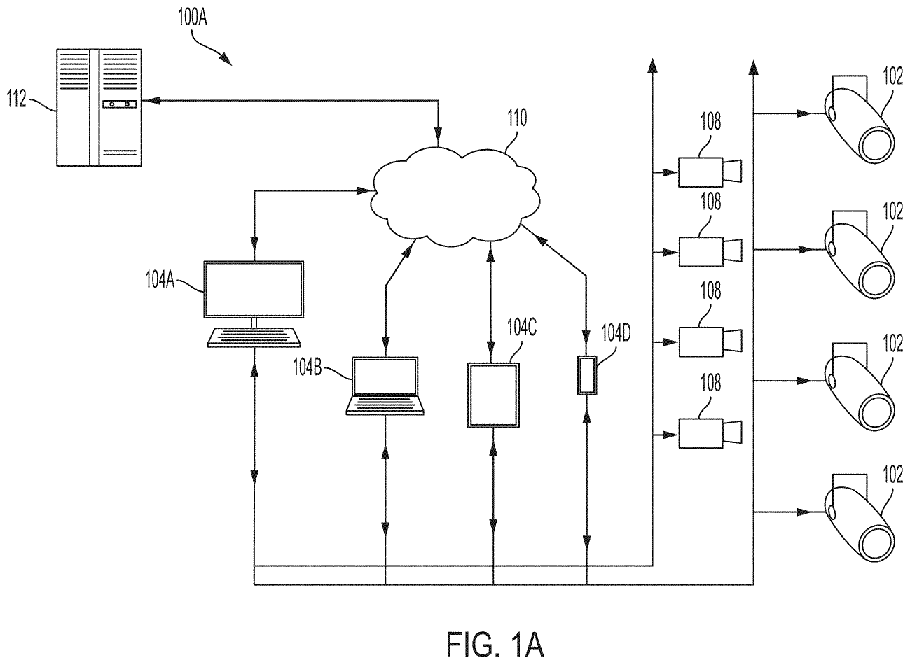

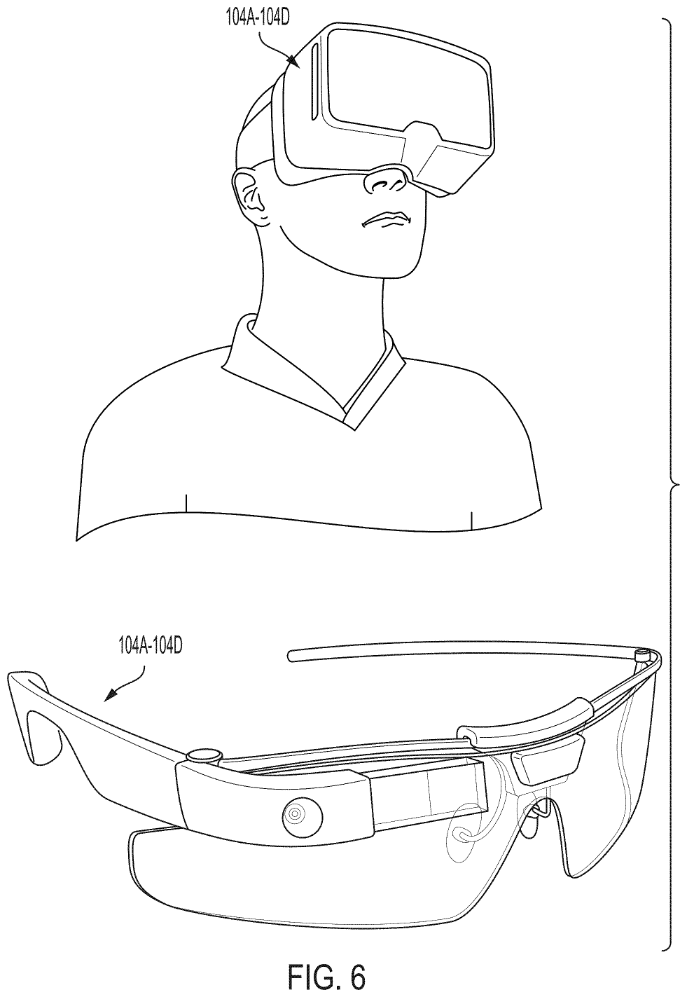

Embodiments described herein provide an augmented reality interface for lighting design and controlling one or more lighting fixtures. For example, FIG. 1 illustrates a system 100 for controlling a lighting fixture 102 using an augmented reality interface. The system 100 includes a user input device 104A-104D, a control board or control panel 106, a lighting fixture 102, cameras 108, a network 110, and a server-side computer or server 112. The user input device 104A-104D includes, for example, a personal or desktop computer 104A, a laptop computer 104B, a tablet computer 104C, or a mobile phone (e.g., a smart phone) 104D. Other user input devices 104 may include, for example, an augmented reality headset or glasses (shown in FIG. 6). In some embodiments, the cameras 108 are integrated with the user input device 104A-104D, such as the camera of the mobile phone 104D. In other embodiments, the cameras 108 are separate from the user input device 104A-104D.

The user input device 104A-104D is configured to communicatively connect to the server 112 through the network 110 and provide information to, or receive information from, the server 112 related to the control or operation of the system 100. The user input device 104A-104D is also configured to communicatively connect to the control board 106 to provide information to, or receive information from, the control board 106. The connections between the user input device 104A-104D and the control board 106 or network 110 are, for example, wired connections, wireless connections, or a combination of wireless and wired connections. Similarly, the connections between the server 112 and the network 110, the control board 106 and the lighting fixtures 102, or the control board 106 and the cameras 108 are wired connections, wireless connections, or a combination of wireless and wired connections.

The network 110 is, for example, a wide area network (“WAN”) (e.g., a TCP/IP based network), a local area network (“LAN”), a neighborhood area network (“NAN”), a home area network (“HAN”), or personal area network (“PAN”) employing any of a variety of communications protocols, such as Wi-Fi, Bluetooth, ZigBee, etc. In some implementations, the network 110 is a cellular network, such as, for example, a Global System for Mobile Communications (“GSM”) network, a General Packet Radio Service (“GPRS”) network, a Code Division Multiple Access (“CDMA”) network, an Evolution-Data Optimized (“EV-DO”) network, an Enhanced Data Rates for GSM Evolution (“EDGE”) network, a 3GSM network, a 4GSM network, a 4G LTE network, a 5G New Radio, a Digital Enhanced Cordless Telecommunications (“DECT”) network, a Digital AMPS (“IS-136/TDMA”) network, or an Integrated Digital Enhanced Network (“iDEN”) network, etc.

FIG. 1A illustrates an alternative system 100A for controlling a lighting fixture 102 using an augmented reality interface. The hardware of the alternative system 100A is identical to the above system 100, except the control board or control panel 106 is removed. As such, the user input device 104A-104D is configured to communicatively connect to the lighting fixture 102 and to the cameras 108. The connections between the user input device 104A-104D and the lighting fixture 102 and the connections between the user input device 104A-104D and the cameras 108 are wired connections, wireless connections, or a combination of wireless and wired connections.

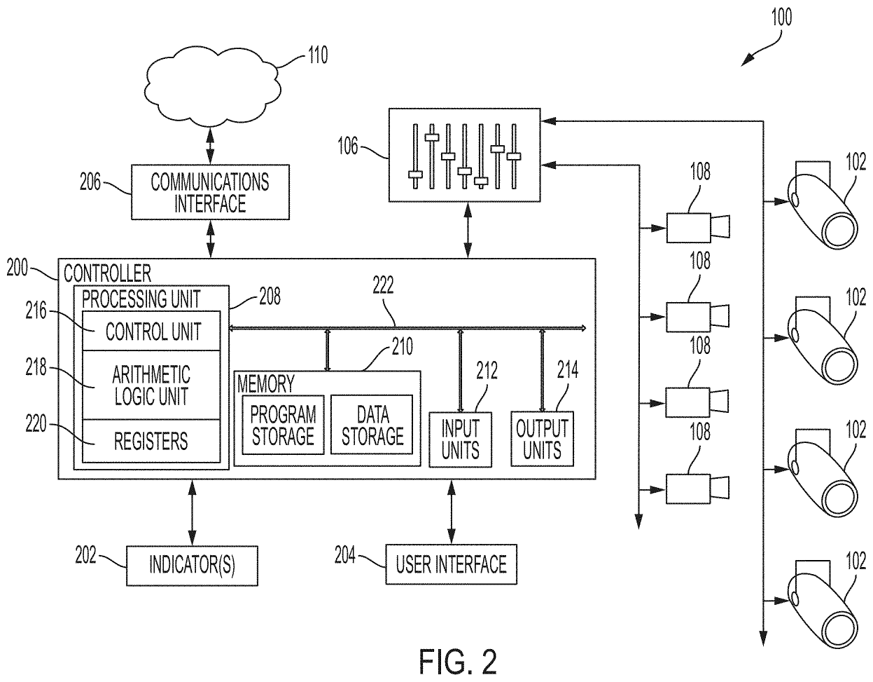

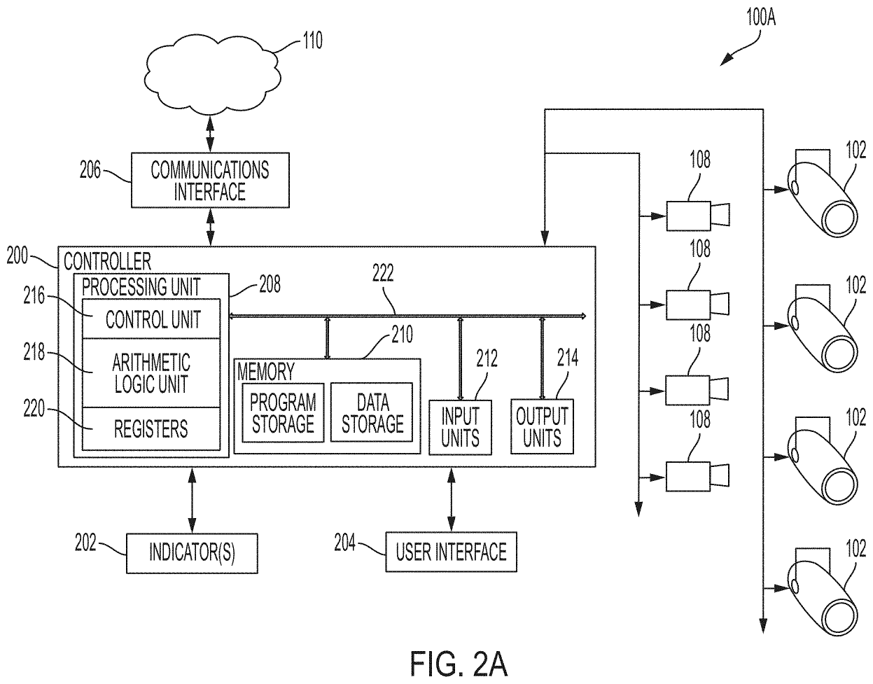

FIG. 2 illustrates a controller 200 for the system 100. The controller 200 is electrically and/or communicatively connected to a variety of modules or components of the system 100. For example, the illustrated controller 200 is connected to one or more indicators 202 (e.g., LEDs, a liquid crystal display [“LCD”], etc.), a user input or user interface 204 (e.g., a user interface of the user input device 104A-104D in FIG. 1), and a communications interface 206. The controller 200 is also connected to the control board 106. The communications interface 206 is connected to the network 110 to enable the controller 200 to communicate with the server 112. The controller 200 includes combinations of hardware and software that are operable to, among other things, control the operation of the system 100, control the operation of the lighting fixture 102, control the operation of the camera 108, receive one or more signals from the camera 108, communicate over the network 110, communicate with the control board 106, receive input from a user via the user interface 204, provide information to a user via the indicators 202, etc. In some embodiments, the indicators 202 and the user interface 204 are integrated together in the form of, for instance, a touch-screen.

In the embodiment illustrated in FIG. 2, the controller 200 is associated with the user input device 104A-104D. As a result, the controller 200 is illustrated in FIG. 2 as being connected to the control board 106 which is, in turn, connected to the lighting fixtures 102 and the cameras 108. In other embodiments, the controller 200 is included within the control board 106, and, for example, the controller 200 can provide control signals directly to the lighting fixture 102s and the cameras 108. In other embodiments, the controller 200 is associated with the server 112 and communicates through the network 110 to provide control signals to the control board 106, the lighting fixtures 102, and/or the cameras 108.

The controller 200 includes a plurality of electrical and electronic components that provide power, operational control, and protection to the components and modules within the controller 200 and/or the system 100. For example, the controller 200 includes, among other things, a processing unit 208 (e.g., an electronic processor, a microprocessor, a microcontroller, or another suitable programmable device), a memory 210, input units 212, and output units 214. The processing unit 208 includes, among other things, a control unit 216, an arithmetic logic unit (“ALU”) 218, and a plurality of registers 220 (shown as a group of registers in FIG. 2), and is implemented using a known computer architecture (e.g., a modified Harvard architecture, a von Neumann architecture, etc.). The processing unit 208, the memory 210, the input units 212, and the output units 214, as well as the various modules or circuits connected to the controller 200 are connected by one or more control and/or data buses (e.g., common bus 222). The control and/or data buses are shown generally in FIG. 2 for illustrative purposes. The use of one or more control and/or data buses for the interconnection between and communication among the various modules, circuits, and components would be known to a person skilled in the art in view of the embodiments described herein.

The memory 210 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 208 is connected to the memory 210 and executes software instructions that are capable of being stored in a RAM of the memory 210 (e.g., during execution), a ROM of the memory 210 (e.g., on a generally permanent basis), or another non-transitory computer readable medium such as another memory or a disc. Software included in the implementation of the system 100 and controller 200 can be stored in the memory 210 of the controller 200. The software includes, for example, firmware, one or more applications, program data, filters, rules, one or more program modules, and other executable instructions. The controller 200 is configured to retrieve from the memory 210 and execute, among other things, instructions related to the control processes and methods described herein. In other embodiments, the controller 200 includes additional, fewer, or different components.

The user interface 204 is included to provide user control of the system 100, the lighting fixtures 102, and/or the cameras 108. The user interface 204 is operably coupled to the controller 200 to control, for example, control or drive signals provided to the lighting fixtures 102 and/or control or drive signals provided to the cameras 108. The user interface 204 can include any combination of digital and analog input devices required to achieve a desired level of control for the system 100. For example, the user interface 204 can include a computer having a display and input devices, a touch-screen display, a plurality of knobs, dials, switches, buttons, faders, or the like. In the embodiment illustrated in FIG. 2, the user interface 204 is separate from the control board 106. In other embodiments, the user interface 204 is included in the control board 106.

The controller 200 is configured to work in combination with the control board 106 to provide direct control or drive signals to the lighting fixtures 102 and/or the cameras 108. As described above, in some embodiments, the controller 200 is configured to provide direct control or drive signals to the lighting fixtures 102 and/or the cameras 108 without separately interacting with the control board 106 (e.g., the control board 106 includes the controller 200). The direct drive signals that are provided to the lighting fixtures 102 and/or the cameras 108 are provided, for example, based on a user input received by the controller 200 from the user interface 204. The controller 200 is also configured to receive one or more signals from the cameras 108 related to image or scan data.

As shown in FIG. 2A and described above, the system 100A includes the controller 200 configured to work without the control board 106, such that the controller 200 is configured to provide signals to the lighting fixtures 102 and/or the cameras 108 and to receive one or more signals from the cameras 108 related to image or scan data.

The controller 200 is configured to implement augmented reality control of the system 100 using, for example, known augmented reality libraries (e.g., ARKit, ARCore, etc.) that come available on or can be added to the user input device 104A-104D. Examples of basic augmented reality displays and controls that can be produced and/or manipulated using the known augmented reality liberates are described in, for example, U.S. Patent Application Publication No. 2011/0221672, published on Sep. 15, 2011, and U.S. Patent Application Publication No. 2004/0046711, published on Mar. 11, 2004, both of which are hereby incorporated by reference.

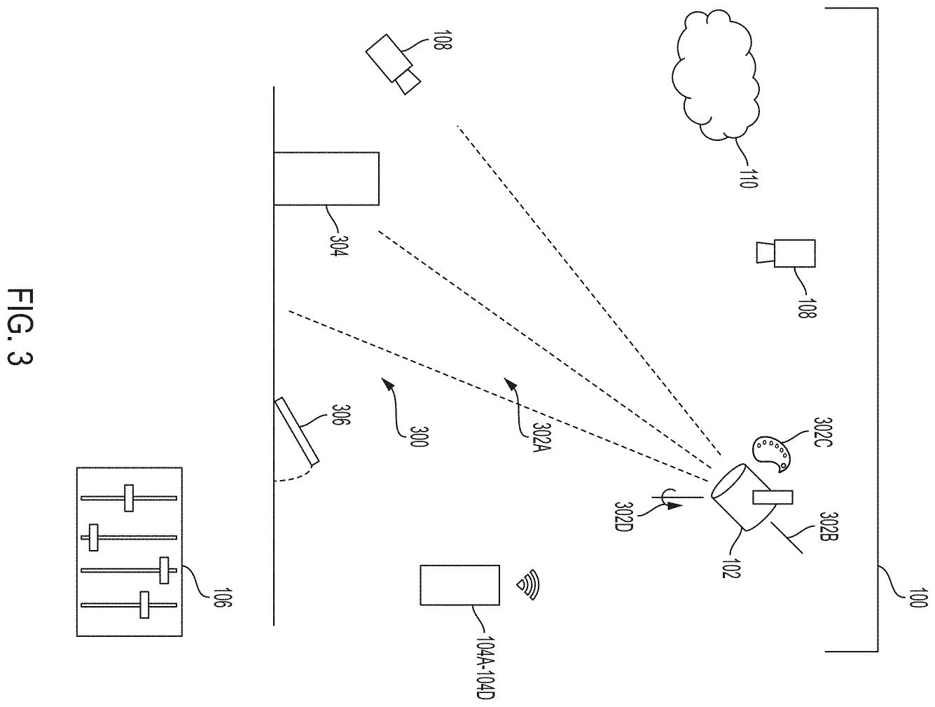

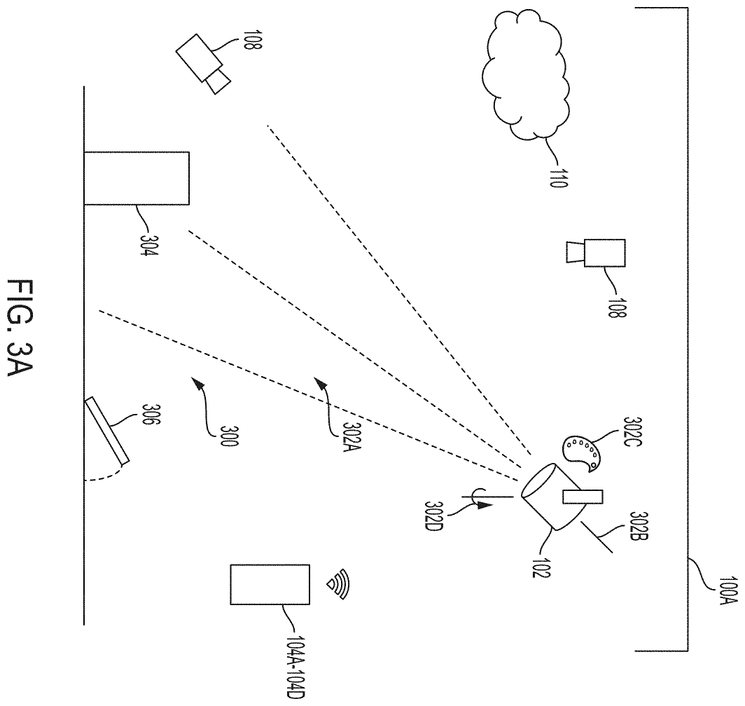

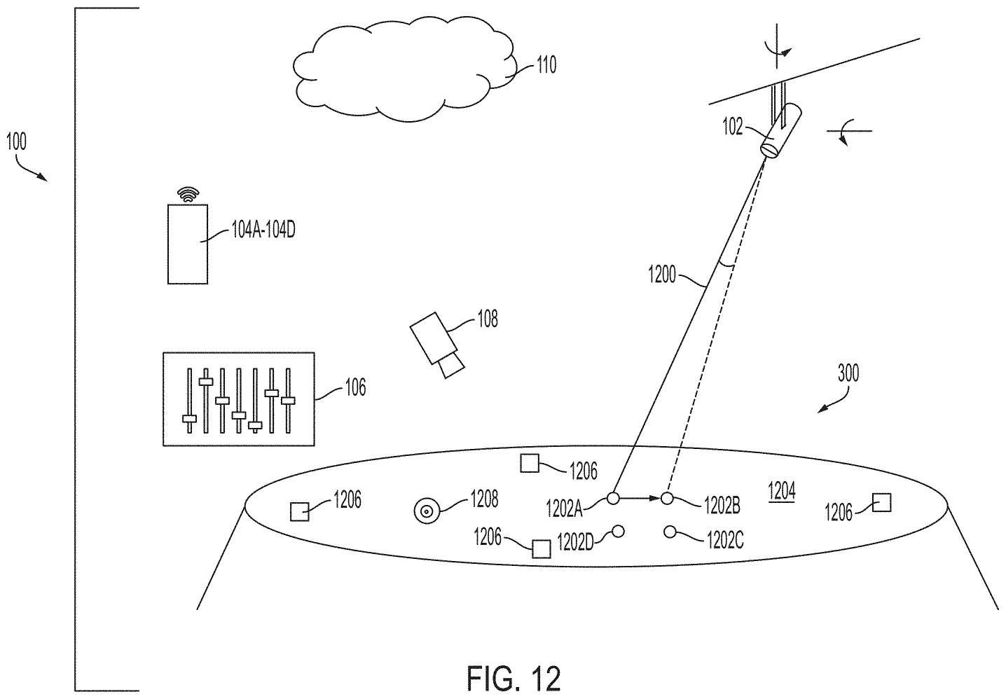

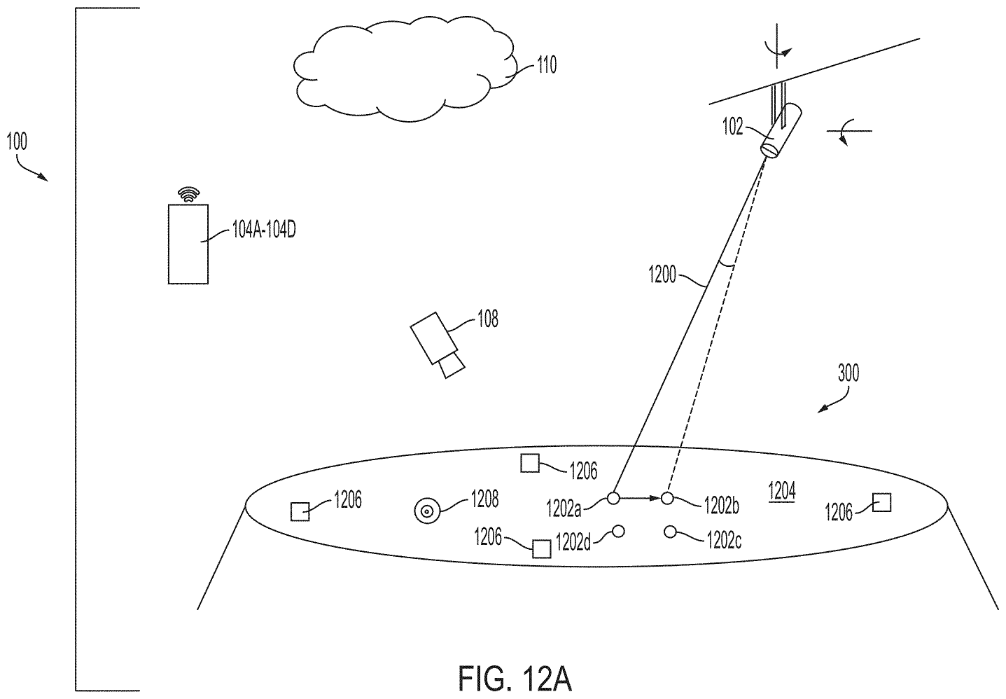

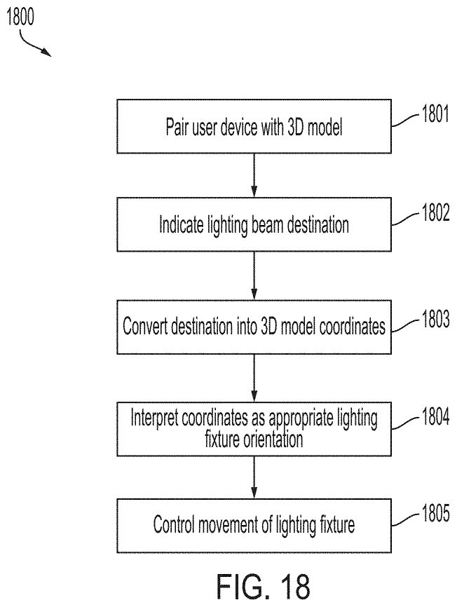

FIG. 3 illustrates the lighting fixture 102, the user input device 104A-104D, the control board 106, and the cameras 108 of the system 100 in a venue 300. The user input device 104A-104D directs the lighting fixture 102 using an augmented reality application run by the controller 200 (e.g., using known augmented reality libraries such as ARKit, ARCore, etc.). The controller 200 receives scan data from the cameras 108 and generates a display. The display includes one or more virtual elements 302A-302D superimposed on the scene captured by the cameras 108. Also illustrated schematically in FIG. 3, the venue 300 includes one or more scenery elements 304, trap doors 306, or the like. The controller 200 determines the location of the user input device 104A-104D in the venue 300 by pairing the user input device 104A-104D with a three-dimensional model space that represents the venue 300. For example, the user input device 104A-104D may locate itself, the lighting fixture 102, and other physical elements in the venue 300 using data received from the cameras 108. A user can also identify multiple reference points or objects located in the venue 300 via an interactive display of the venue 300 on the user input device 104A-104D. In some embodiments, the controller 200 generates a three-dimensional model of the venue 300 including a coordinate system that locates the positions of lighting fixture 102 and other objects or surfaces in the venue 300 relative to reference points that are located in the venue 300. Pairing the user input device 104A104D with a three-dimensional model space for locating objects within the three-dimensional model space is described in greater detail below with respect to FIGS. 12-18.

FIG. 3A illustrates the system 100A in the venue 300. As described above, the system 100A removes the control board 106, and the user input device 104A-104D is configured to directly communicate with the lighting fixture 102 and the cameras 108.

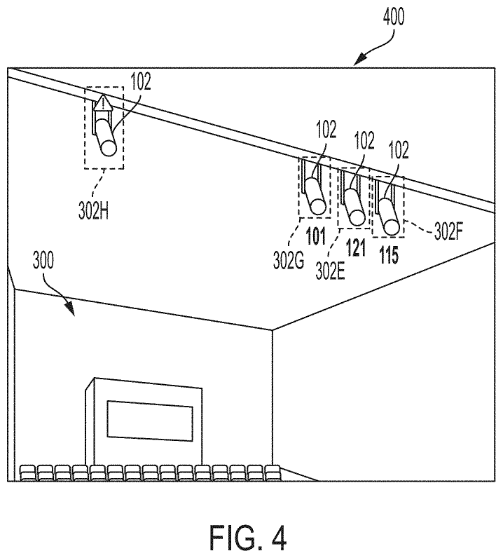

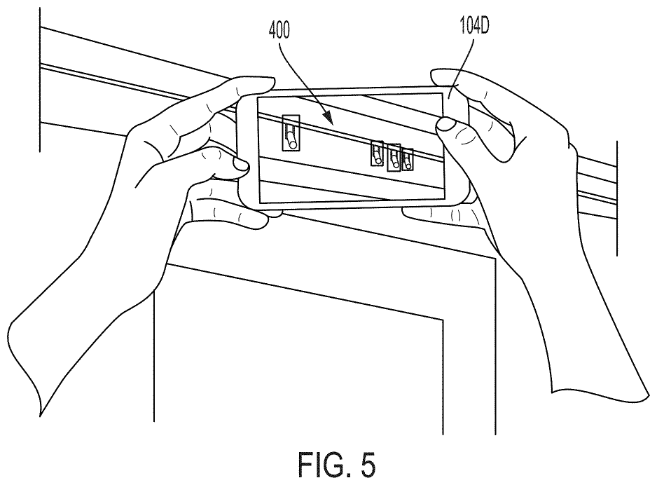

FIG. 4 illustrates an application display 400 including representations of lighting fixtures 102 and virtual elements 302E-302H. This application display 400 is displayed on the user input device 104A-104D, such as the smartphone 104D shown in FIG. 5 or the augmented reality headset/glasses shown in FIG. 6, to be interacted with by the user. The display 400 may be a screen, projection, transparent overlay device, or the like. The scene at the venue 300 is captured by the cameras 108 and augmented with one or more virtual elements 302E-302H. Particularly, the one or more virtual elements 302E-302H are shown in the application display 400 as superimposed over the captured scene. The virtual elements 302E-302H may be interactive such that the controller 200 may receive a user input via the one or more virtual elements 302E-302H. Examples of virtual elements 302A-302H to be shown on the display 400 include a virtual light beam 302A (see FIG. 3), a virtual zoom axis 302B (see FIG. 3), a color palette 302C of light that can be produced by the lighting fixture 102 (see FIG. 3), a virtual pan axis 302D (see FIG. 3), a virtual tilt axis, a virtual switch, a virtual knob, a virtual button, a virtual shutter, manufacturer data 302E of the lighting fixture 102 (see FIG. 4), channel numbers 302F (see FIG. 4), digital multiplex (or DMX) addresses 302G (see FIG. 4), diagnostic information relating to the lighting fixture 302H (see FIG. 4), information relating to the light configured to be produced by the lighting fixture 102, a bounding box for selecting a particular lighting fixture 102, or the like.

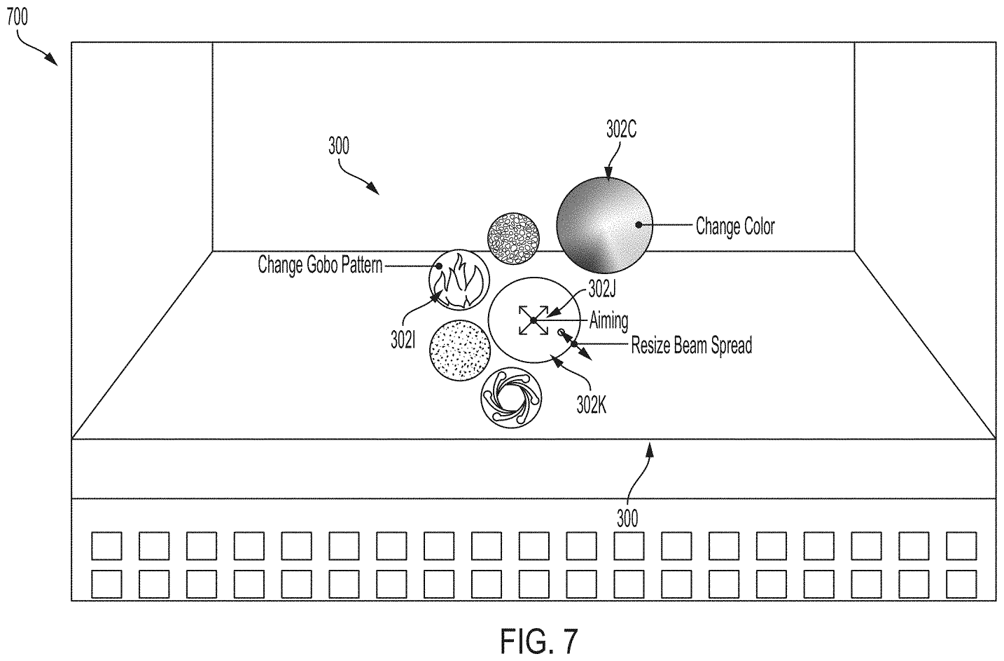

FIG. 7 illustrates an application display 700 including a scene captured by the cameras 108 at the venue 300. In some embodiments, the scene captured for the display 700 may not show any of the one or more lighting fixtures 102. The display 700 may include, for instance, the stage 1204 (see FIG. 12), a scenery element 304, a person, or the like. As described above, the display 700 is augmented with one or more virtual elements 302A-302H. Examples of virtual elements to be shown on the display 700 include a color palette 302C, a go between or go before optics template (“gobo”) selection icon 3021, a beam centroid aiming icon 302J, a beam spread resizing icon 302K, a virtual hoist control to initiate movement of a scenery element, a virtual outline indicating an area that is dangerous for an actor or performer to stand, a virtual scenery element, or the like.

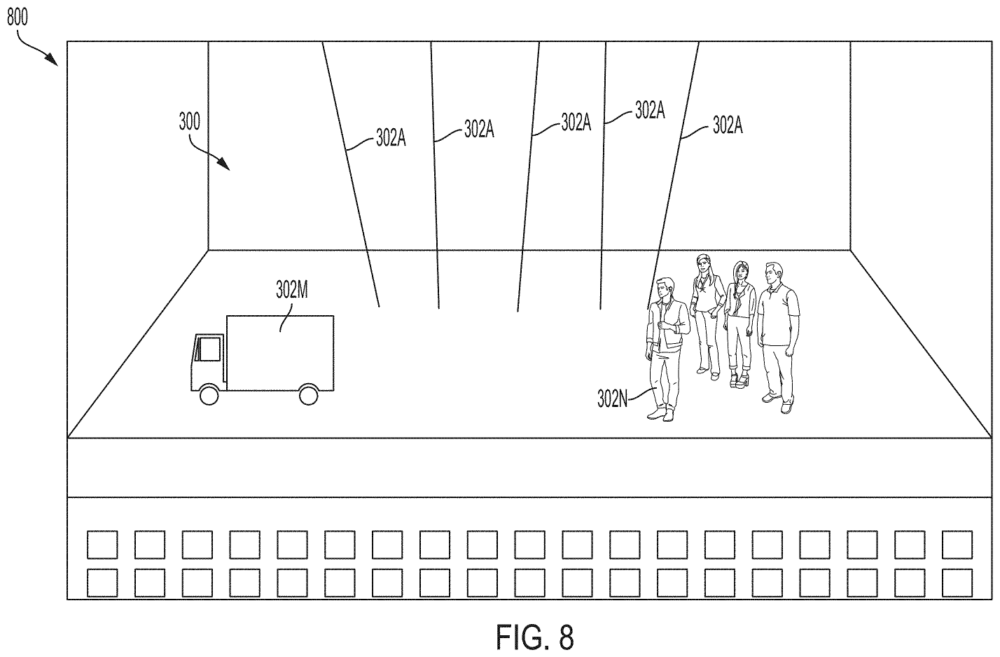

FIG. 8 illustrates another application display 800 including a scene captured by the cameras 108 at the venue 300. The scene captured for the display 800 may not show any of the one or more lighting fixtures 102. As described above, the display 800 is augmented with one or more virtual elements. Examples of virtual elements to be shown on the display 800 include one or more virtual light beams 302A, lighting rendering of a virtual scenery element 302M, lighting rendering of a virtual performer 302N, or combinations thereof.

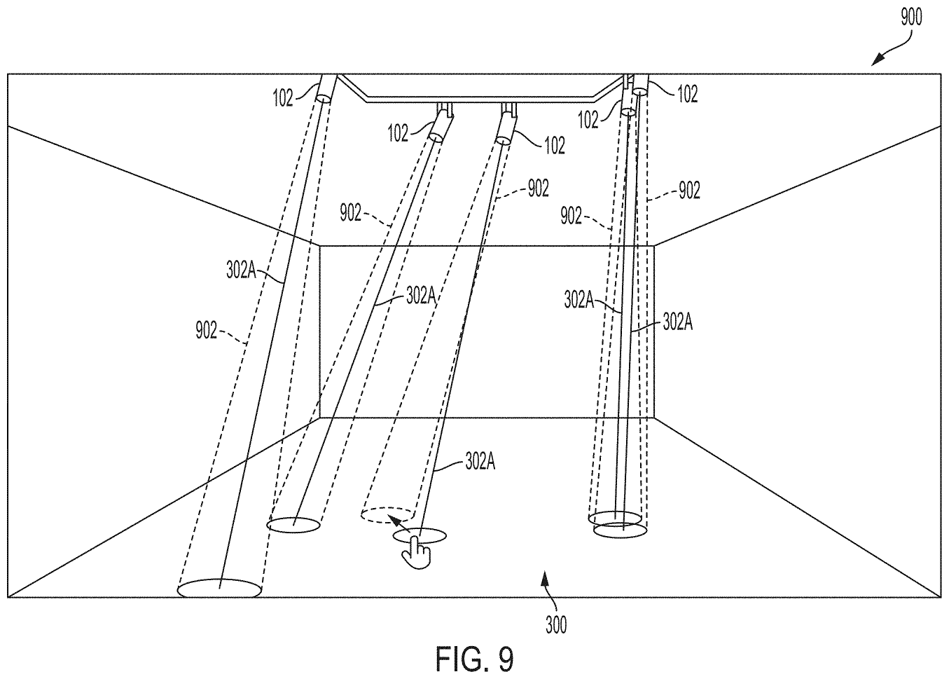

FIG. 9 illustrates another application display 900 that includes the stage 1204 (see FIG. 12) of the venue 300 as well as the one or more lighting fixtures 102. As described above, the display 900 is augmented with one or more virtual elements. In this application display 900, calibration of the one or more lighting fixtures 102 is also possible in addition to the above-described features. The display 900 shows the virtual light beam 302A of each lighting fixture 102, as well as the actual light beam 902 of each lighting fixture 102 that is illuminated. If one of the lighting fixtures 102 requires calibrating, the user may observe in the application display 900 that the actual light beam 902 does not match the virtual light beam 302A. The beams 902, 302A may differ in color, focus/size, location, shape, or the like. In such a situation, the user adjusts the lighting fixture 102 to calibrate it by, for example, adjusting the pan and tilt of the lighting fixture 102 by interacting with virtual pan and tilt axes. Once the beams 902, 302A match, the user can consider the lighting fixture 102 to be calibrated. Further, the user uses the display 900 to estimate the pose of the lighting fixture 102 in order to input the pose estimation data into a database or calculation for later use.

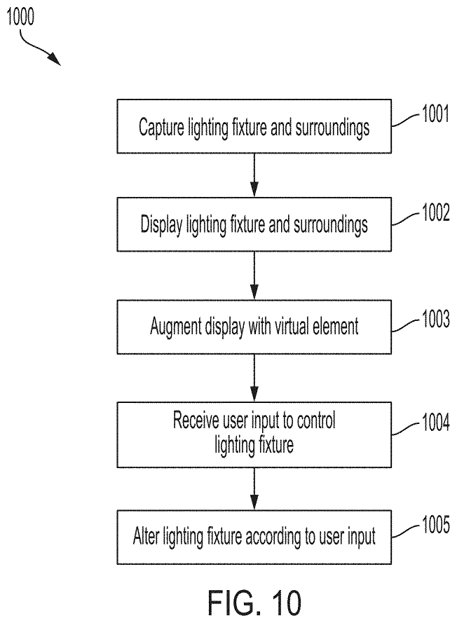

As shown in FIG. 10, the system 100, 100A may operate according to a method 1000 to control a lighting fixture 102. First, the lighting fixture 102 and the surroundings of the lighting fixture 102 in a venue 300 are captured with one or more cameras 108 (STEP 1001). In some embodiments, the location and/or orientation of the cameras 108 (e.g., a pose of each of the cameras 108) are also determined. The lighting fixture 102 and the surroundings in the venue 300 are displayed in an application display 400, 700, 800, and/or 900 (STEP 1002). The application display 400, 700, 800, and/or 900 is augmented with one or more virtual elements 302A-302N (STEP 1003).

The method 1000 further includes receiving user input via a user interface to control the lighting fixture 102 (STEP 1004). The user input can be an interaction with a touch screen, a voice command, a hand gesture captured by one or more scanners (such as the cameras 108), an acceleration or positional change detected by one or more sensors in the user device 104A-104D, or the like. Additionally, the user input can be an interaction with the one or more virtual elements 302A-302N in the application display 400, 700, 800, and/or 900. For instance, the user can grab and move a virtual light beam 302A, a virtual shutter, a virtual knob, or the like in the application display 400, 700, 800, and/or 900.

The method 1000 also includes altering a characteristic of the lighting fixture 102 in some manner in response to the received user input (STEP 1005). For instance, the user input of moving the virtual light beam 302A in the application display 400, 700, 800, and/or 900 can be received by the controller 200, which transmits a control or drive signal to cause the lighting fixture 102 to move to an angular pan/tilt position that directs the light beam 902 toward the new light beam destination. As described above, other potential user inputs can change a color, focus, brightness, and the like of the light produced by the lighting fixture 102. In addition to altering the lighting fixture 102 according to the user input, the method 1000 also includes (as part of STEP 1005) updating the application display 400, 700, 800, and/or 900 to reflect the real-world changes made to the lighting fixture 102. These changes include altering the values associated with various settings of the lighting fixture 102 or the virtual elements 302A-302N.

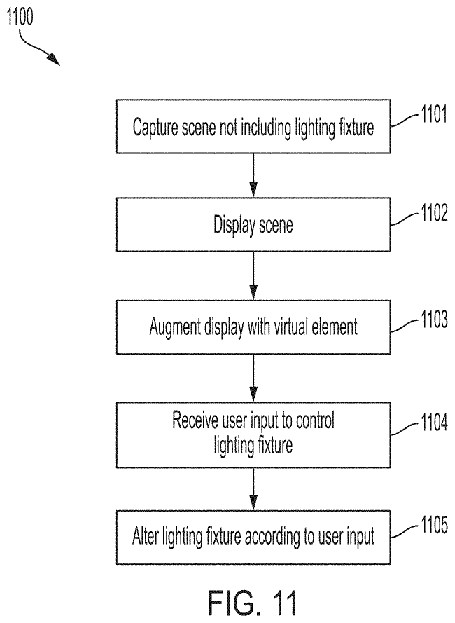

As shown in FIG. 11, the system 100, 100A may additionally or alternatively operate according to a method 1100 to control a lighting fixture 102. First, a scene (e.g., a portion of the venue 300) to be illuminated by the lighting fixture 102 is captured with the cameras 108 (STEP 1101). In some embodiments, this scene may not show the lighting fixture 102 that is to be controlled according to the method 1100. In some embodiments, the location and/or orientation of the cameras 108 (e.g., a pose of each of the cameras 108) is also be determined. The method 1100 further includes displaying the scene of the venue 300 in an application display 700, 800 (STEP 1102). The application display 700, 800 is then augmented with one or more virtual elements 302A-302N (STEP 1103).

The method 1100 further includes receiving a user input to control the lighting fixture 102 (STEP 1104). The user input can be an interaction with the one or more virtual elements 302A-302N in the application display 700, 800. For instance, the user can grab and move a light beam 302A, a scenery element 304, or the like as described above.

The method 1100 also includes altering the lighting fixture 102 in response to the received user input (STEP 1105). For instance, the user input of moving the virtual light beam 302A in the display 700, 800 causes the lighting fixture 102 to move to a corresponding angular pan or tilt position that re-creates the moved virtual light beam 302A in the real-world venue 300. For example, the controller 200 may receive the user input and determine a lighting fixture 102 pose that would implement the moved virtual light beam in the real-world venue 300. The controller 200 transmits a control or drive signal to the lighting fixture 102, or to the control board 106, to control the lighting fixture 102 according to the movement of the virtual light beam 302A in the display 700, 800. Other potential user inputs can be received via the display 700, 800 for changing a color, focus, brightness, or the like of the light produced by the lighting fixture 102 and can initiate a corresponding change in the lighting fixture 102 in the real-world venue 300. The user inputs could additionally or alternatively control hoisting motors for the real-world scenery elements 304, motors for the trap door 306, smoke machines, or the like.

Pairing the user input device 104A-104D with a three-dimensional model space for locating objects within the three-dimensional model space is described with respect to FIGS. 12-18. By being able to accurately locate objects from the real-world in a three-dimensional model space, the augmented reality application displays 400, 700, 800, and/or 900 can accurately represent the real-world and correctly position virtual elements 302A-302N in the application display 400, 700, 800, and/or 900 with respect to real-world elements of the venue 300.

FIG. 12 illustrates the control board 106, the lighting fixture 102, the camera 108, and the user input device 104A-104D of the system 100 in the venue 300. The user input device 104A-104D directs the lighting fixture 102 such that a lighting beam 1200 projecting from the lighting fixture 102 strikes at discrete locations 1202A, 1202B, 1202C, 1202D on a stage surface 1204 at the venue 300. In some embodiments, a user directly controls the movement of the lighting fixture 102, or the lighting fixture 102 may move according to a preprogrammed pattern.

FIG. 12A illustrates the system 100A in the venue 300. As described above, the system 100A removes the control board 106, and the user input device 104A-104D is configured to directly communicate with the lighting fixture 102 and the camera 108.

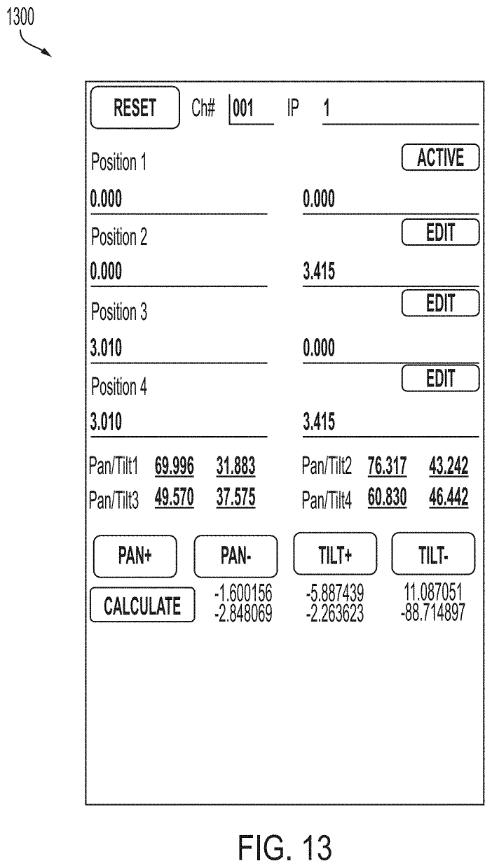

With reference to the system 100 and/or the system 100A, FIG. 13 illustrates an example of an application interface screen 1300 for use with the user device 104A-104D that receives user input to control the movement of the lighting fixture 102 for synchronizing the position of the lighting beam 1200 with the discrete locations 1202 on the ground in the venue 300. In some embodiments, the lighting beam 1200 moves to at least three locations (1202A, 1202B, 1202C). Other embodiments include the lighting beam 1200 moving to a fourth location 1202D. Other embodiments include the lighting beam 1200 moving to more than four locations 1202. The movement of the lighting fixture 102 is accomplished by changing the angle of the lighting fixture 102 by either panning or tilting the lighting fixture 102.

The controller 200 is configured to store the angular change data corresponding to the lighting fixture 102 movement to move the lighting beam 1200 from the first location 1202A to the second location 1202B, from the second location 1202B to the third location 1202C, and so on.

With reference to FIGS. 12 and 12A, the controller 200 is further configured to store the coordinate data of each of the at least three locations 1202 on the surface 1204. In some embodiments, the coordinate data is input by a user, such as when the user directly controls the movement of the lighting fixture 102. In some embodiments, the coordinate data is determined by the controller 200 by calculating a position of the user device 104A-104D relative to one or more reference points 1206 with scan data from one or more cameras 108. The cameras 108 may be integrated into the user device 104A-104D, wirelessly connected to the user device 104A-104D, connected by wire to the user device 104A-104D, or otherwise associated. The reference points 1206 provide orientation and distance information for the user device 104A-104D. In some embodiments, the reference points 1206 are visible marks on the surface 1204. Other embodiments include at least one reference point 1206 in the form of a sensor readable marker that is not visible to the human eye (e.g., an infrared marker). Using known computer vision, image recognition, and scanning applications (e.g., a simultaneous localization and mapping [“SLAM”] program), the controller 200 can calculate distances between designated points on the surface 1204 after the user device 104A-104D has been properly calibrated with the reference points 1206.

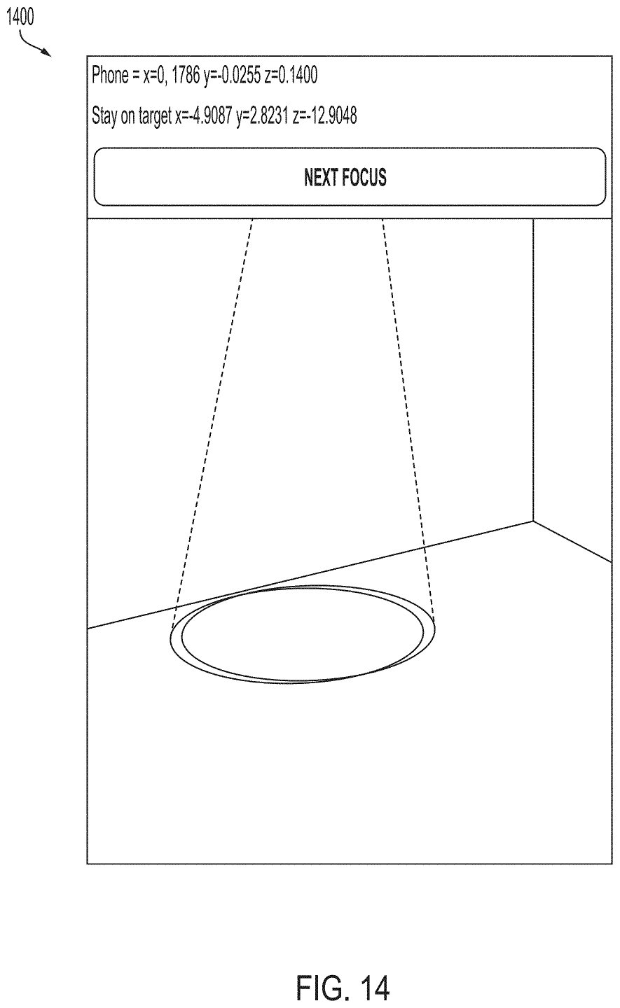

To determine the discrete locations 1202 where the lighting beam 1200 contacts the surface 1204 without user input information regarding the locations, the controller 200 is configured to determine a centroid of the lighting beam through scan data provided by the camera 108. An example of the scan of the surface 1204 that the camera 108 may perform is shown in FIG. 14. The centroid can be found regardless of angle of attack of the lighting beam 1200 through any appropriate method including, for example, light intensity analysis of the surface 1204. As such, at each of the discrete locations 1202, the image data of the lighting beam 1200 is captured by the camera 108 and analyzed by the controller 200. Once the analysis is complete, the controller 200 is configured to return values for the coordinate data of each of the discrete locations 1202 relative to the one or more reference points 1206.

Because the lighting fixture 102 control is paired with the controller 200, the controller 200 is able to quantify the change in angle each time the lighting fixture 102 moves. Although this change in angle is known to the controller 200 as a relative angle of the lighting fixture 102 from one position to another and not an absolute angle relative to the surface 1204, the absolute angles can be found through mathematical calculations using a perspective inversion solution described generally below.

To calculate the position of the lighting fixture 102 relative to the stage surface 1204, the perspective inversion solution uses the length of each side of a triangle that is traced by the lighting beam 1200 on the stage surface 1204 and the changes in angle of the lighting fixture 102 that created that triangle. The length of the sides of the triangle can be found with the at least three locations 1202 coordinate data input and/or calculation as described above. The angles are known by virtue of the controller 200 controlling the lighting fixture 102, as described above.

Because there can be a degree of uncertainty present when calculating the position of the lighting fixture 102 based on only three discrete locations 1202A, 1202B, and 1202C, some embodiments include a fourth discrete location 1202D. With four discrete locations 1202A, 1202B, 1202C, 1202D, the controller 200 is configured to sequentially determine sets of three discrete locations (e.g., 1202A, 1202B, and 1202C first, 1202B, 1202C, and 1202D second, 1202A, 1202C, and 1202D third, etc.) and is configured to return a value for the lengths of the lighting beam 1200 as it existed when it was directed to each of the discrete locations 1202A, 1202B, 1202C, 1202D. The controller 200 is then configured to compare these results as they overlap in order to calculate the values with greater certainty. Other embodiments include more than the four discrete locations 1202. Such embodiments add even further accuracy to the calculation. Once the length of the lighting beam 1200 from the lighting fixture 102 to each individual discrete location 1202A, 1202B, 1202C, 1202D is found, the controller 200 is configured to, for example, trilaterate or quadrilaterate the location of the lighting fixture 102. The point at which the spheres of possible solutions for the discrete locations 1202A, 1202B, 1202C, 1202D cross is designated as the location of the lighting fixture 102. This calculation actually returns two results—one above the stage surface 1204 and one below the stage surface 1204. The controller 200 is configured to discard the result below the stage surface 1204.

In some embodiments of the system 100 and/or the system 100A, the controller 200 is further configured to run an optimizer operation with the possible positions of the lighting fixture 102. Because the measurements could be off slightly or the control feedback may have noise in the signal, an optimizer operation can more accurately determine the position of the lighting fixture 102 (e.g., improve accuracy of the position of the lighting fixture). The optimizer runs calculations using the law of cosines with the values it has from previously running the perspective inversion solution. The optimizer takes the length of the lighting beam 1200 from the lighting fixture 102 to each individual discrete location 1202A, 1202B, 1202C, 1202D, combines that data with the known changes in angle of the lighting fixture 102, and determines possible values for the distances on the stage surface 1204 between the discrete locations 1202A, 1202B, 1202C, 1202D. Because these distances are known through measurement or other methods described above, the optimizer compares these known distances with the determined distances to gauge the accuracy of the results from the perspective inversion solution.

An example of an appropriate optimizer operation is a limited memory Broyden-Fletcher-Goldfarb-Shanno (“LBFGS”) optimizer, although other optimizer operations may be used. If the optimizer operation returns results that converge to a value, that particular value is determined to be more accurate than the initial value. If the results do not converge to a value and instead scatter, the initial value is returned as accurate enough to continue without further attempting the optimizer operation. After these steps, the location of the lighting fixture 102 is again trilaterated (or quadrilaterated). This location is then output as the most accurate estimation of the position of the lighting fixture 102 relative to the stage surface 1204 (or the reference points 1206).

After the controller 200 has determined the position of the lighting fixture 102, the controller 200 is configured to determine the orientation of the lighting fixture 102 relative to the stage surface 1204. In some embodiments, however, the position calculation for the lighting fixture 102 and the orientation calculation for the lighting fixture 102 are both accomplished with the optimizer operation.

The controller 200 uses any three of the discrete locations 1202 on the stage surface 1204 and the corresponding relative angular change information from the control of the lighting fixture 102. The relative angular change information includes pan, tilt, or both pan and tilt. The controller 200 determines spherical coordinates of the discrete locations 1202 receiving the lighting beam 1200 as the lighting fixture 102 is oriented in each position. These spherical coordinates are relative spherical coordinates, in that they include pan and tilt angles of the lighting fixture 102 relative to the axis of the lighting beam 1200, and the origin is the position of the lighting fixture 102 (i.e., the focal point of the lighting beam 1200).

The controller 200 is configured to translate the known Cartesian coordinates of the found position of the lighting fixture 102 and the known discrete locations 1202 relative to the reference points 1206 into real-world spherical coordinates with the lighting fixture 102 as the origin. Some embodiments include the reference points 1206 being one of the known discrete locations 1202 in this calculation.

The controller 200 is then configured to perform a matrix transformation utilizing both the relative spherical coordinates and the real-world spherical coordinates to translate the relative spherical coordinates of the orientation of the lighting fixture 102 at each position into real-world spherical coordinates (e.g. relative to a reference plane, which may be referred to as absolute spherical coordinates). Once this relationship is determined, the yaw, pitch, and roll information of the orientation of the lighting fixture 102 relative to the stage surface 1204 is extracted. In some embodiments, the yaw, pitch, and roll may be referred to as absolute angles of the lighting fixture 102 with reference to the surface 1204, which includes a plane of the discrete locations 1202A, 1202B, 1202C, and 1202D. This information is the absolute orientation of the lighting fixture 102 regardless of mounting methods.

After the above calculations have been completed, the controller 200 is configured to present the results as the indicated position and orientation of the lighting fixture 102 (e.g., the controller 200, or a user device 104A-104D is paired with the three-dimensional model space of the venue). With this information, the controller 200 can alter image data relating to the lighting fixture 102 and the lighting beam 1200 in an interactive environment and control the lighting fixture 102. Once the lighting fixtures 102 in the venue 300 have been identified, classified, and located, the above calculated information can be used to implement transitions of various styles.

With continued reference to FIGS. 12 and 12A, the above calculated information can also be used to alter command string data sent to the lighting fixture 102 in order to translate locations 1208 designated on the surface 1204 into appropriate angular changes of the lighting fixture 102 to cause the lighting beam 1200 to be directed to the designated locations 1208. Some embodiments of the system 100, 100A include the controller 200 configured to control the lighting fixture 102 according to the altered command string data.

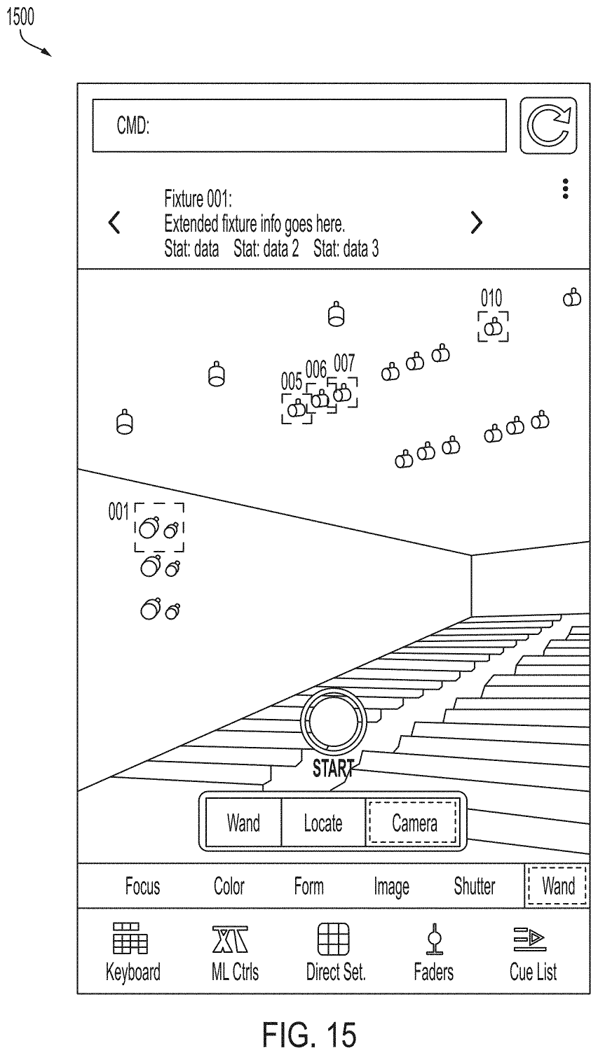

In some embodiments, the indication of the locations 1208 is made on a touchscreen of the user device 104A-104D utilizing an augmented reality interface (through, for instance, an application interface screen 1500 as shown in FIG. 15). In such an interface, the user sees the surface 1204 on the touchscreen and may point to a destination 1208 on the surface 1204 on the touchscreen. The controller 200 is configured to then convert this indicated portion of the screen into an equivalent position of the destination 1208 on the surface 1204. The controller 200 is configured to relate the orientation of the capture view of the camera 108 with the surface 1204 based on a calibration with one or more reference points 1206. Additionally or alternatively, the system 100, 100A uses one or more inertial measurement units (“IMUs”) coupled with the user device 104A-104D to determine the position and orientation data of the user device 104A-104D. Cameras 108 may not be necessary in this instance, but the user device 104A-104D would be paired to the three-dimensional model space by positioning and orienting the device in a known home arrangement and recording the data from the IMUs at that home arrangement. In embodiments of the system 100, 100A using augmented reality libraries (e.g., ARCore, ARKit, etc.), both IMUs and cameras 108 can be utilized to improve accuracy of the data.

Once the real-world position of the destination 1208 on the surface 1204 is determined, the controller 200 is configured to send a control signal to one or more motors to actuate movement of the lighting fixture 102. The lighting fixture 102 moves to the appropriate orientation to project the lighting beam 1200 at the destination 1208. For example, the controller 200 is configured to translate the real-world Cartesian coordinates of the destination 1208 into the altered control string described above to operate the lighting fixture 102 such that the lighting beam 1200 moves appropriately in the three-dimensional model space.

In some embodiments of the system 100, 100A, the indication of the desired destination 1208 for the lighting beam 1200 on the surface 1204 at the venue 300 can be made by aiming the center of the capture view of the camera 108 at the destination 1208. As described above, the controller 200 is configured to convert this center of the capture view into an equivalent positon of the destination 1208 on the actual surface 1204. In this configuration, the indication of the desired destination 1208 may be actuated by a distinct command, such as a voice command, the press of a button, or the like. Additionally or alternatively, the indication of the desired destination 1208 is switched to a continual or continuous mode, such that the desired destination 1208 moves simultaneously or with some delay relative to the changing capture view of the camera 108 as the camera 108 is moved throughout the venue 300. In some embodiments, this mode can be used as a follow spot control.

In some embodiments of the system 100, 100A, the indication of the desired destination 308 of the lighting beam 1200 on the surface 1204 at the venue 300 is made by pointing an end of the user device 104A-104D in a direction with the camera view of the camera 108 pointing in an orthogonal direction. With a smartphone 104D, for instance, a user could point the top end of the smartphone 106D at the desired location 1208 while the camera 108 is directed toward the surface 1204. In this configuration, the lighting beam destination 1208 may be set at a constant distance, potentially designated by the user, from the end of the smartphone 104D or from the center of the capture view of the camera 108 in an orthogonal direction from the direction of the capture view. In some embodiments, the user device 104A-104D determines the location of the desired destination 1208 by pointing the end of the user device 104A-104D to the desired destination 1208, and using the known location (coordinates) of the user device 104A-104D in the venue along with a tilting angle of the device 104A-104D relative to the surface 1204 (e.g., determined using internal IMUs of the device 104A-104D) to determine the location of the of the desired destination 1208 in the venue 300.

In some embodiments of the system 100, 100A, the indication of the desired destination 1208 of the lighting beam 1200 is set as the location of the user device 104A-104D itself. The controller 200 determines the location of the user device 104A-104D based on the capture data from the camera 108. This data is processed to calculate the location relative to one or more reference points 1206. The controller 200 is configured to designate the current location of the user device 104A-104D relative to the reference points 1206 as the destination 1208. As described above, the indication of the desired destination 1208 as the location of the user device 104A-104D can be actuated by a distinct command. Additionally or alternatively, the indication of the user device 104A-104D as the destination 1208 may be switched to a continuous or continual mode.

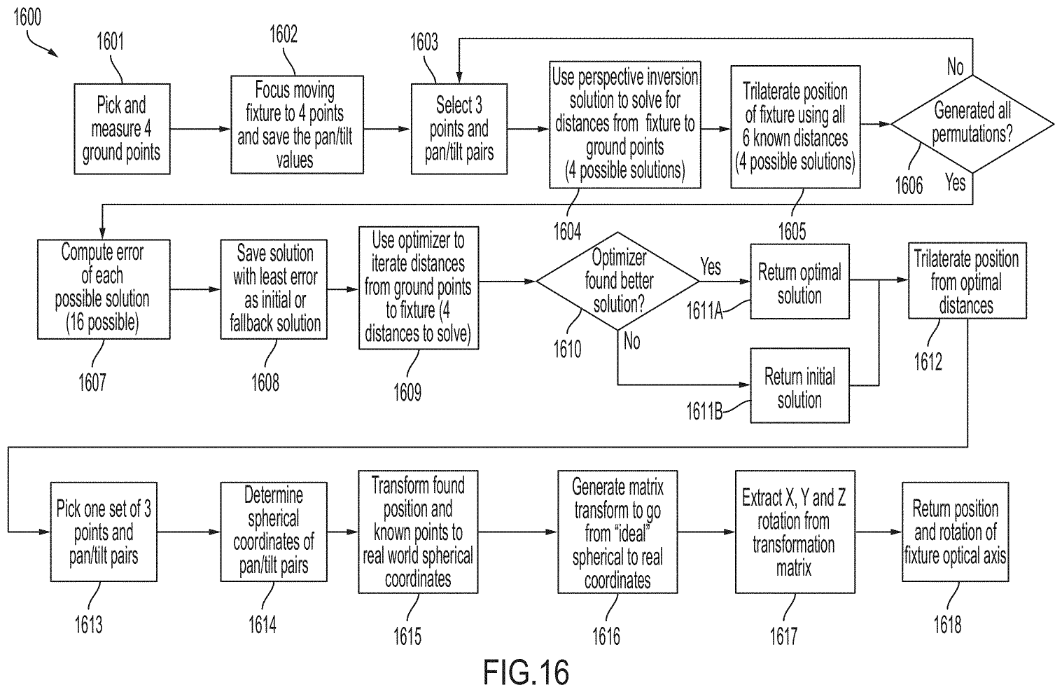

As shown in FIG. 16, the system 100, 100A may operate according to a method 1600 to calculate the arrangement information of the lighting fixture 102. First, the user chooses and measures four discrete physical locations 1202A, 1202B, 1202C, 1202D on the surface 1204 (STEP 1601).

The user then focuses the lighting fixture 102 at each of the four discrete locations 1202A, 1202B, 1202C, 1202D and saves the resulting angular change values for the pan and tilt of the lighting fixture (STEP 1602). Next, either the controller 200 or the user selects any three of the four discrete locations 1202A, 1202B, 1202C, 1202D and the corresponding angular changes the lighting fixture 102 made to direct the lighting beam 1200 to each of the respective selected discrete locations 1202A, 1202B, 1202C, 1202D (STEP 1603).

A perspective inversion solution is used to solve for the distances from the discrete locations 1202A, 1202B, 1202C, 1202D on the surface 1204 to the lighting fixture 102 (STEP 1604). Once all the values for the distances have been determined, the position of the lighting fixture 102 is trilaterated (STEP 1605).

The controller 200 then determines whether all of the possible combinations of three of the discrete locations 1202A, 1202B, 1202C, 1202D and corresponding angular changes have been calculated with the perspective inversion solution (STEP 1606). If not all possible combinations have been calculated, the method 1600 returns to STEP 1603 to complete the other possible combinations.

If, at STEP 1606, all possible combinations have been calculated, the method 1600 proceeds to compute an error of each possible solution found (STEP 1607). Next, the controller 200 saves the solution with the fewest errors as the best initial solution for the position of the lighting fixture 102 (STEP 1608). The best initial solution is then used as an input to attempt to optimize (e.g., improve accuracy of) the result by running calculations using the law of cosines (STEP 1609). The controller 200 then determines whether the optimization operation converged on a solution (STEP 1610).

If the optimization operation converged on a solution, the optimal solution is returned as the solution for the length of the light beam 1200 from each of the discrete locations 1202A, 1202B, 1202C, 1202D to the lighting fixture 102 (STEP 1611A) instead of the previous best initial solution from STEP 1608. If the optimization operation did not converge on a solution, the controller 200 ignores the optimization operation and returns the best initial solution from STEP 1608 (STEP 1611B). The controller 200 then determines the position of the lighting fixture 102 through trilateration with the best available lengths (STEP 1612).

Now that the position of the lighting fixture 102 has been determined, the controller 200 selects one set of three of the discrete locations 1202 and the corresponding changes in angle of the lighting fixture 102 (STEP 1613). The spherical coordinates of the discrete locations 1202 are found with the lighting fixture 102 serving as the point of origin (STEP 1614). Then, the known Cartesian coordinates of the discrete locations 1202 and the lighting fixture 102 are converted to real-world spherical coordinates (STEP 1615) with the lighting fixture 102 as the origin. A matrix transformation is performed to translate the relative spherical coordinates of the lighting fixture 102 into absolute spherical coordinates (STEP 1616). The yaw, pitch, and roll information of the lighting fixture 102 is then determined and extracted (STEP 1617). The controller 200 then returns the position and orientation of the lighting fixture 102 relative to the surface 1204 and the reference point 1206 (STEP 1618).

Although STEPS 1613-1617 were described above, some embodiments of the method 1600 includes the position calculation for the lighting fixture 102 and the orientation calculation for the lighting fixture 102 both being accomplished during the optimization step (STEP 1609) and proceeding from STEP 1612 directly to STEP 1618.

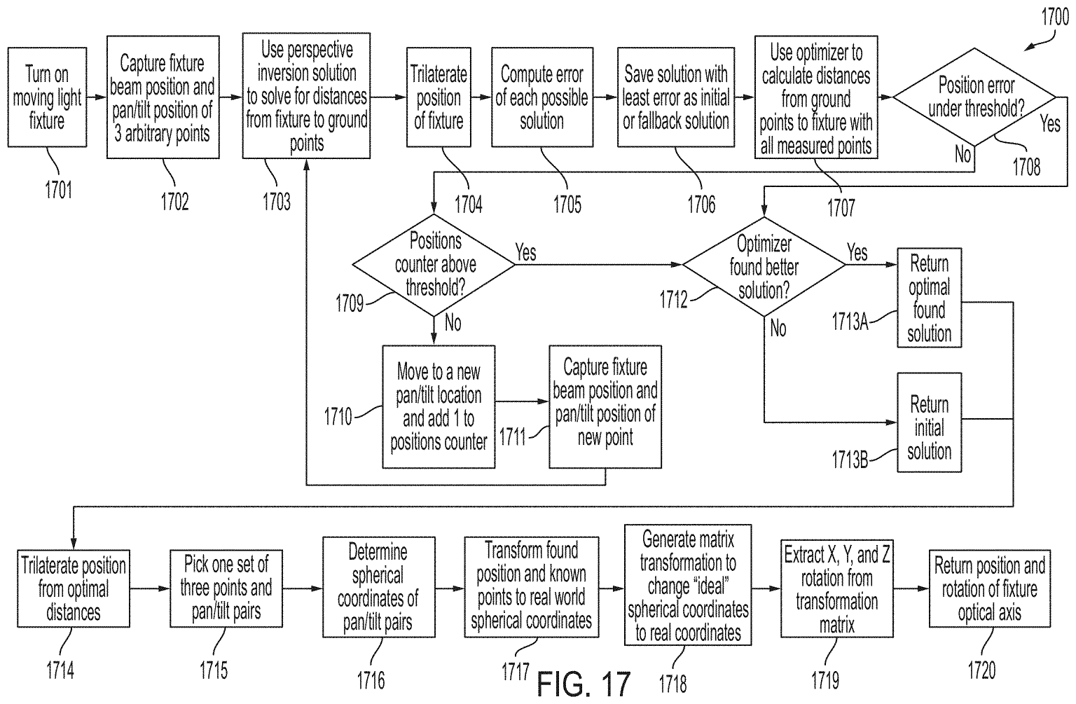

With reference to FIG. 17, the system 100, 100A may additionally or alternatively operate according to a method 1700 to calculate the arrangement information of the lighting fixture 102. First, the lighting fixture 102 is turned on (STEP 1701). A control routine is operated, and the controller 200 records the set angle of the lighting fixture 102 while the camera 110 captures the discrete location 1202 of the lighting beam 1200 on the surface 1204 at three arbitrary points (STEP 1702). The controller 200 then calculates the distances from the discrete locations 1202 to the lighting fixture 102 (STEP 1703). These distances are used to trilaterate the position of the lighting fixture 102 (STEP 1704).

The method 1700 then moves to STEP 1705, where the error of each possible solution is calculated. The controller 200 saves the solution with the least errors as the best initial solution for the position of the lighting fixture 102 (STEP 1706). The best initial solution is used as an input to attempt to optimize the result by running calculations using the law of cosines (STEP 1707). The controller 200 then determines whether the initial solution (after optimization) for the position of the lighting fixture 102 is known with enough accuracy to be below an error threshold (STEP 1708).

If the position error is not less than the error threshold at STEP 1708, the controller 200 determines whether the number of discrete locations 1202 recorded by a positions counter is above a threshold value (STEP 1709). The threshold positions value may be any appropriate number including, for instance, ten discrete locations 1202. If, at STEP 1709, the positions counter is less than the threshold value, the controller 200 moves the lighting fixture 102 to a new angular position (STEP 1710) and increases the value stored in the positions counter by one. Next, the controller 200 captures data corresponding to another discrete location 1202 (STEP 1711). After capturing the data corresponding to another discrete location 1202 (STEP 1711), the method 800 returns to STEP 1703 to recalculate the distances from the discrete locations 1202 to the lighting fixture 102. The method 1700 continues through STEPS 1704-1707.

This portion of the method 1700 loops until either the initial solution (after optimization) is found within the error threshold or the number stored in the positions counter is above the threshold value. In some embodiments, the addition of the fourth discrete location 1202D makes the initial solution fall within the error threshold. In other embodiments, five or more discrete locations 1202 are used. In other embodiments, only the initial three discrete locations 1202A, 1202B, and 1202C are used to get an initial solution that is within the error threshold. If, at STEP 1708, position error is less than or equal to the error threshold, the method 1700 continues to STEP 1712. Similarly, if the new initial solution found at STEP 1706 is sufficiently accurate after optimization and after the method 1700 has continued through the loop of STEPS 1707-1711 and 1703-1708, the method 1700 continues to STEP 1712. Further, if the initial solution found at STEP 1706 and optimized at STEP 1707 is not within the error threshold but the positions counter has a value that is above the positions threshold, the method 1700 continues to STEP 1712 without trying further discrete locations 1202.

The controller 200 then determines whether the optimization operation converged on a solution (STEP 1712). If the optimization operation converged on a solution, the optimal solution is returned as the solution for the lengths of the light beam 1200 from each of the discrete locations 1202 to the lighting fixture 102 (STEP 1713A) instead of the previous best initial solution from STEP 1706. If the optimization operation did not converge on a solution, the controller 200 ignores the optimization operation and returns the best initial solution from STEP 1706 (STEP 1713B). The controller 200 then calculates the position of the lighting fixture 102 for a final time through trilateration with the best available values for the lengths from the discrete locations 1202 to the lighting fixture 102 (STEP 1714).

With the position of the lighting fixture 102 determined, the controller 200 selects one set of three of the discrete locations 1202 and the corresponding changes in angle of the lighting fixture 102 (STEP 1715). The spherical coordinates of the discrete locations 302 are found with the lighting fixture 102 serving as the point of origin (STEP 1716). Then, the known Cartesian coordinates of the discrete locations 1202 and the lighting fixture 102 are converted to real-world spherical coordinates (STEP 1717) with the lighting fixture 102 as the origin. A matrix transformation is performed to translate the relative spherical coordinates of the lighting fixture 102 into absolute spherical coordinates (STEP 1718). The yaw, pitch, and roll information of the lighting fixture 102 is then found and extracted (STEP 1719). The controller 200 then determines the position and orientation of the lighting fixture 102 relative to the surface 1204 and the reference point 1206 (STEP 1720).

Although STEPS 1715-1719 were described above, some embodiments of the method 1700 include the position calculation for the lighting fixture 102 and the orientation calculation for the lighting fixture 102 both being accomplished during the optimization step (STEP 1707) and proceeding from STEP 1714 directly to STEP 1720.

With reference to FIG. 9, a method 1800 of directing a lighting fixture 102 in the venue 300 is shown. The system 100, 100A may additionally or alternatively operate according to the method 1800. The method 1800 begins with pairing the user device 104A-104D in the venue 300 with a three-dimensional model space of the lighting beam 1200 and lighting fixture 102 (STEP 1801). This step is accomplished, for instance, by directing the camera 108 such that the capture view of the camera scans at least one of the reference points 1206. Once the reference points 1206 have been scanned, the controller 200 can determine where the user device 104A-104D is in the venue 300 and what orientation it has in the venue 300 (e.g., as described above with respect to FIGS. 12 and 12A).

The method 1800 also includes the controller 200 indicating a lighting beam destination 1208 (STEP 1802). The lighting beam destination 1208 may be designated in, for instance, one of the ways described above. The lighting beam destination 1208 is located relative to the capture view of the camera 108. Once the lighting beam destination 1208 has been indicated, the method 1800 includes the controller 200 converting the destination indicated by the user device 104A-104D into coordinates at the venue 300 in the three-dimensional model space (STEP 1803). This conversion is made based on the earlier gathered data about the orientation and position of the user device 104A-104D.

After this conversion has been made, the method 1800 includes the controller 200 interpreting the coordinates at the venue 300 for the lighting beam destination 1208 relative to lighting fixture arrangement (e.g., positions and orientations), and determining a corresponding lighting fixture 102 arrangement (e.g., using method 1600 or method 1700) that directs the lighting beam 1200 appropriately to the lighting beam destination 1208 (STEP 1804). The method 1800 then includes the controller 200 controlling actuation of at least one motor coupled to or associated with the lighting fixture 102 to move the lighting fixture 102 according to the determined lighting fixture 102 orientation such that the lighting beam 1200 is directed to the lighting beam destination 1208 (STEP 1805).

Thus, embodiments described herein provide methods and systems for controlling one or more lighting fixtures through interaction with an augmented reality display. Various features and advantages of some embodiments are set forth in the following claims.

What is claimed is:

1. A method of controlling a lighting fixture, the method comprising:
capturing, using a camera, image data of the lighting fixture;
generating, using an electronic processor, a display including a representation of the lighting fixture on a display device;
generating, using the electronic processor, one or more virtual elements;
augmenting, using the electronic processor, the representation of the lighting fixture in the display with the one or more virtual elements;
receiving, with the electronic processor, an input via the one or more virtual elements in the display to control the lighting fixture; and
generating, using the electronic processor, a control signal to alter a characteristic of the lighting fixture in response to the input.

2. The method of claim 1, wherein the display includes surroundings of the lighting fixture that are captured in the image data of the lighting fixture.

3. The method of claim 1, wherein:
the one or more virtual elements include interactive virtual elements; and
the receiving, with the electronic processor, the input via the one or more virtual elements to control the lighting fixture includes receiving the input as a result of user interaction with the one or more virtual elements in the display.

4. The method of claim 1, further comprising:
generating, using the electronic processor, the display with the one or more virtual elements in a changed state after generating the control signal in response to the input.

5. The method of claim 1, wherein the control signal is operable for changing a brightness of light produced by the lighting fixture, changing a color of light produced by the lighting fixture, changing a focus of light produced by the lighting fixture, and/or changing an angular position of the lighting fixture.

6. The method of claim 1, wherein the one or more virtual elements include manufacturer data of the lighting fixture, channel numbers of the lighting fixture, digital multiplex addresses of the lighting fixture, diagnostic information of the lighting fixture, a slider, a switch, a knob, a button a virtual shutter, a virtual axis of one of pan and tilt of the lighting fixture, a color palette, information relating to light produced by the lighting fixture, and/or a selection box surrounding the lighting fixture to allow the user to select the lighting fixture for the altering of the lighting fixture.

7. A system for controlling a lighting fixture, the system comprising:
a display device; and
a controller including an electronic processor coupled to a memory, the memory storing instructions that when executed by the electronic processor, configure the controller to:
receive image data of the lighting fixture from a camera,
generate a display including a representation of the lighting fixture on a display device,
generate one or more virtual elements,
augment the representation of the lighting fixture in the display with the one or more virtual elements,
receive an input via the one or more virtual elements in the display to control the lighting fixture, and
generate a control signal to alter a characteristic of the lighting fixture in response to the input.

8. The system of claim 7, wherein the display includes surroundings of the lighting fixture that are captured in the image data of the lighting fixture.

9. The system of claim 7, wherein:
the one or more virtual elements include interactive virtual elements; and
the input is received as a result of user interaction with the one or more virtual elements in the display.

10. The system of claim 7, wherein the controller is further configured to generate the display with the one or more virtual elements in a changed state after the control signal is generated in response to the input.

11. The system of claim 7, wherein the control signal is operable to change a brightness of light produced by the lighting fixture, change a color of light produced by the lighting fixture, change a focus of light produced by the lighting fixture, and/or change an angular position of the lighting fixture.

12. The system of claim 7, wherein the one or more virtual elements includes manufacturer data of the lighting fixture, channel numbers of the lighting fixture, digital multiplex addresses of the lighting fixture, diagnostic information of the lighting fixture, a slider, a switch, a knob, a button a virtual shutter, a virtual axis of one of pan and tilt of the lighting fixture, a color palette, information relating to light produced by the lighting fixture, and/or a selection box surrounding the lighting fixture to allow the user to select the lighting fixture for the altering of the lighting fixture.

13. A method of controlling a device in a lighting system, the method comprising:
capturing, with a camera, an image of a scene to be illuminated by a lighting fixture;
generating, using an electronic processor, a display including a representation of the scene on a display device;
generating, using the electronic processor, one or more virtual elements associated with the device;
augmenting, using the electronic processor, the representation of the scene in the display with the one or more virtual elements;
receiving, with the electronic processor, an input via the one or more virtual elements in the display to control the device in the lighting system; and
generating, using the electronic processor, a control signal to alter a characteristic of the device in response to the input.

14. The method of claim 13, wherein:
the one or more virtual elements include interactive virtual elements; and
the receiving, with the electronic processor, the input via the one or more virtual elements to control the device includes receiving the input as a result of user interaction with the one or more virtual elements in the display.

15. The method of claim 13, further comprising:
generating, using the electronic processor, the display with the one or more virtual elements in a changed state after generating the control signal in response to the input.

16. The method of claim 13, wherein the control signal is operable for changing a brightness of light produced by the lighting fixture, changing a color of light produced by the lighting fixture, changing a focus of light produced by the lighting fixture, and/or changing an angular position of the lighting fixture.

17. The method of claim 13, wherein the one or more virtual elements include a virtual beam of light associated with a lighting fixture, a hoist control to initiate movement of scenery elements, a scenery element, an outline indicating a danger area, a trap door, a fan, and/or a smoke machine.

18. A system for controlling a device in a lighting system, the system comprising:
a display device; and
a controller including an electronic processor coupled to a memory, the memory storing instructions that when executed by the electronic processor, configure the controller to:
receive image data of a scene to be illuminated by a lighting fixture from a camera,
generate a display including a representation of the scene on a display device,
generate one or more virtual elements associated with the device,
augment the representation of the scene in the display with the one or more virtual elements,
receive an input via the one or more virtual elements in the display to control the device in the lighting system, and
generate a control signal to alter a characteristic of the device in response to the input.

19. The system of claim 18, wherein:
the one or more virtual elements include interactive virtual elements; and
the receiving of the input via the one or more virtual elements to control the device includes receiving the input as a result of user interaction with the one or more virtual elements in the display.

20. The system of claim 18, wherein the controller is configured to generate the display with the one or more virtual elements in a changed state after the control signal is generated in response to the input.

21. The system of claim 18, wherein the control signal is operable to change a brightness of light produced by the lighting fixture, change a color of light produced by the lighting fixture, change a focus of light produced by the lighting fixture, and/or change an angular position of the lighting fixture.

22. The system of claim 18, wherein the one or more virtual elements include a virtual beam of light associated with a lighting fixture, a hoist control to initiate movement of scenery elements, a scenery element, an outline indicating a danger area, a trap door, a fan, and/or a smoke machine.
